(19) United States
(12) Patent Application Publication
(10) Pub. No.: US 2013/0033805 A1
(43) Pub. Date: Feb. 7, 2013

(54) BASE UNIT ADAPTED TO PROVIDE A COMMUNICATIONS CONNECTION AS WELL AS A METHOD OF PROVIDING A COMMUNICATIONS CONNECTION

(71) Applicants: Andreas Harving Holm, Copenhagen (DK); Ole Konarski, Skovlunde (DE)

(72) Inventors: Andreas Harving Holm, Copenhagen (DK); Ole Konarski, Skovlunde (DE)

(73) Assignee: GN Netcom A/S, Bellerup (DK)

(21) Appl. No.: 13/552,888

(22) Filed: Jul. 19, 2012

Related U.S. Application Data
(63) Continuation of application No. 12/063,059, filed on Mar. 23, 2010, now abandoned.

(30) Foreign Application Priority Data
Aug. 12, 2005 (DK) PA200501134

(51) Int. Cl. H05K 7/00

(52) U.S. Cl. 361/679.01

(57) ABSTRACT

A base unit, which is arranged to provide a communications connection between a plurality of fixed communications units and at least one mobile communications unit, such as a headset, is arranged to adapt the bandwidth of the communications connection between the fixed communications units, which operate at various bandwidths, and the mobile units. The fixed communications units may be public switched telephones, PC phones, PDA units, etc. The invention makes it possible to optimize the sound quality in dependence on which type of fixed communications unit is coupled to the mobile unit, and which task is to be solved. In one embodiment, it is possible to lock the bandwidth, e.g. to the lowest bandwidth, irrespective of which fixed communications connection is used.

The invention relates to a base unit adapted to provide a communications connection between a plurality of fixed communications units and a mobile communications unit.

The invention moreover relates to a method of providing a communications connection between a plurality of fixed communications units and a mobile communications unit via a base unit, said base unit comprising a plurality of connection terminals for connecting the fixed communications units.

Nowadays, telephone calls are established wirelessly to a great extent by means of mobile communications connections, such as headsets which may be coupled to various types of fixed installations, such as public switched telephones, PC phones, PDA (Personal Digital Assistant) units, etc.

Since the fixed installations frequently operate with various bandwidths when transferring data and/or speech, there is a need for the ability to adapt the mobile telephone connections to fixed communications connections independently of the bandwidths at which the fixed communications connections operate.

It is also desirable to be able to adapt a mobile communications connection to a plurality of fixed communications connections, so that it is possible to select a specific communications connection for a given task.

Accordingly, an object of the invention is to provide a communications connection, where the flexibility with respect to possible communications connections between a plurality of fixed communications units and one or more mobile communications connections may be provided.

The object of the invention is achieved by a communications connection of the type defined in the introductory portion of claim 1, which is characterized in that the base unit contains a control circuit and a plurality of connection terminals for connecting the fixed communications units, said control unit being arranged to set-up a connection between a selected connection terminal and the mobile communications unit and to adapt the bandwidth in a wireless connection between the base unit and the mobile communications unit in dependence on the selected connection terminal.

Hereby, a user using a mobile communications unit will get access to a plurality of fixed communications units which with respect to bandwidth may easily be adapted to a given task, thereby ensuring an optimum sound quality.

In other words, unduly high bandwidth will not be used for a fixed communications unit requiring a lower bandwidth, which, in turn, means a lower consumption of power, a better range, and that the maximum number of units which may be present in a room may be increased.

For optimum selection of bandwidth, it is expedient, as stated in claim 2, that the control circuit is arranged to adapt the bandwidth in the wireless connection in dependence on the bandwidth in an incoming signal on the selected connection terminal, or, as stated in claim 3, that the control circuit is arranged to receive a control signal from the mobile communications unit and to adapt the bandwidth in the wireless connection in dependence on the control signal, or, as stated in claim 4, that control circuit is arranged to adapt the bandwidth in the wireless connection in dependence on a user input.

When, as stated in claim 5, the control circuit is arranged to receive the user input from a keyboard on the base unit irrespective of which communications unit transfers the call, or, as stated in claim 6, that the control circuit is arranged to receive the user input from a keyboard on the mobile communications unit, or, as stated in claim 7, that the control circuit is arranged to receive a user input which comprises a selection of connection terminal, or, as stated in claim 8, that the control circuit is arranged to receive a user input which comprises a selection of a specific bandwidth in the wireless connection, a high degree of user flexibility is achieved, where bandwidth requirements of a user for a given task may easily be adapted to the nature of the task.

Expediently, as stated in claim 9, the base unit comprises a plurality of switches which are arranged to selectively set-up a connection between one or more communications units and the mobile communications unit.

With a view to avoiding the situation that several fixed communications units are coupled to the mobile communications unit at the same time, it is advantageous if, as stated in claim 10, the base unit is arranged to set-up a connection between one or more fixed communications units and the mobile communications unit by precisely one switch.

A particularly expedient way of connecting the base unit to the fixed communications units is, as stated in claim 11, that the base unit comprises a plurality of USB inputs, a plurality of PSTN inputs, and a plurality of other input which enable connection of the fixed communications units, or, as stated in claim 12, that it comprises one or more USB inputs which enable connection of a fixed communications unit in the form of a PC phone, or, as stated in claim 13, that it comprises one or more PSTN inputs which enable connection of a fixed communications unit in the form of a public switched telephone.

It is moreover expedient if, as stated in claim 14, the base unit is arranged to enable connection of a mobile communications unit in the form of a headset via the wireless connection.

Typical bandwidth requirements for the transfer of data and/or speech are, as stated in claim 15, that the base unit operates at bandwidths which are 4 kHz or 8 kHz.

As mentioned, the invention also relates to a method.

This method is characterized in that the base unit contains a control circuit and a plurality of connection terminals for connecting the fixed communications units, said control circuit being arranged to set-up a connection between a selected connection terminal and the mobile communications unit and to adapt the bandwidth in a wireless connection between the base unit and the mobile communications unit in dependence on the selected connection terminal.

Expedient embodiments of the method are defined in claims 17-23.

The invention will now be explained more fully with reference to the drawing, in which

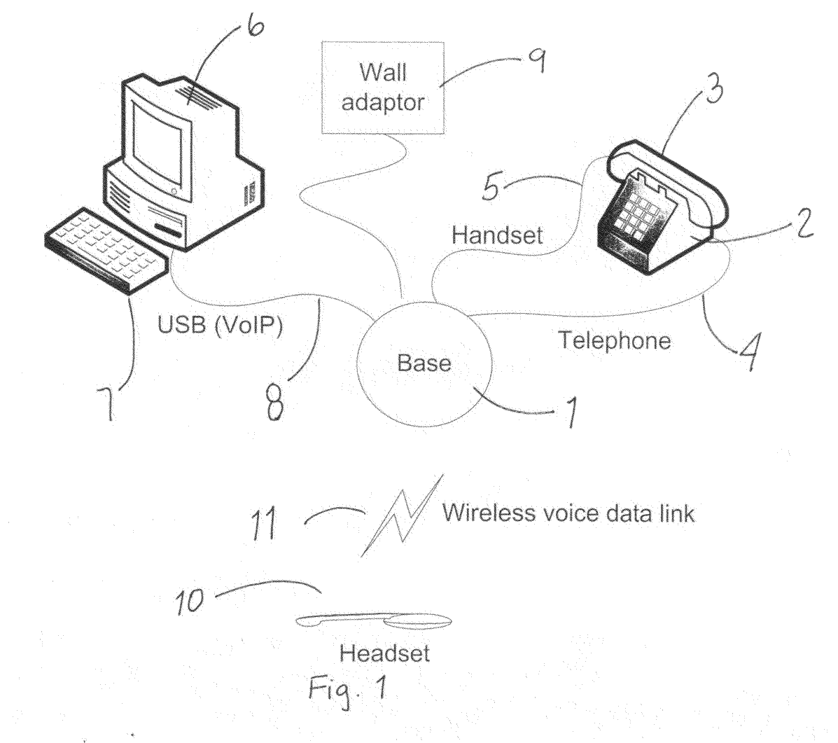

FIG. 1 shows the basic structure of a communications connection according to the invention,

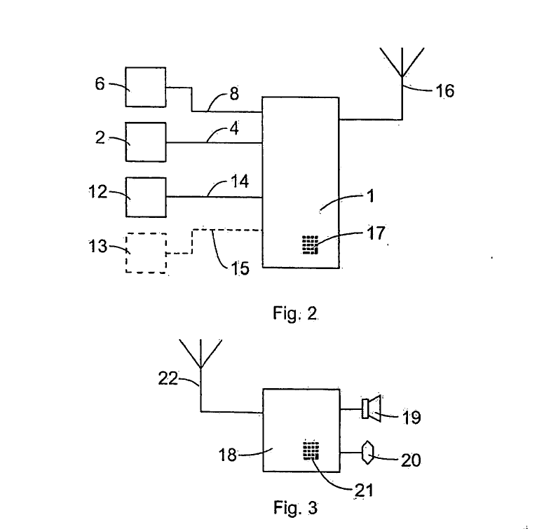

FIG. 2 shows a block diagram of how a base unit according to the invention forms part of the communications connection of FIG. 1,

FIG. 3 shows the structure of a mobile unit which forms part of the communications connection of FIG. 1,

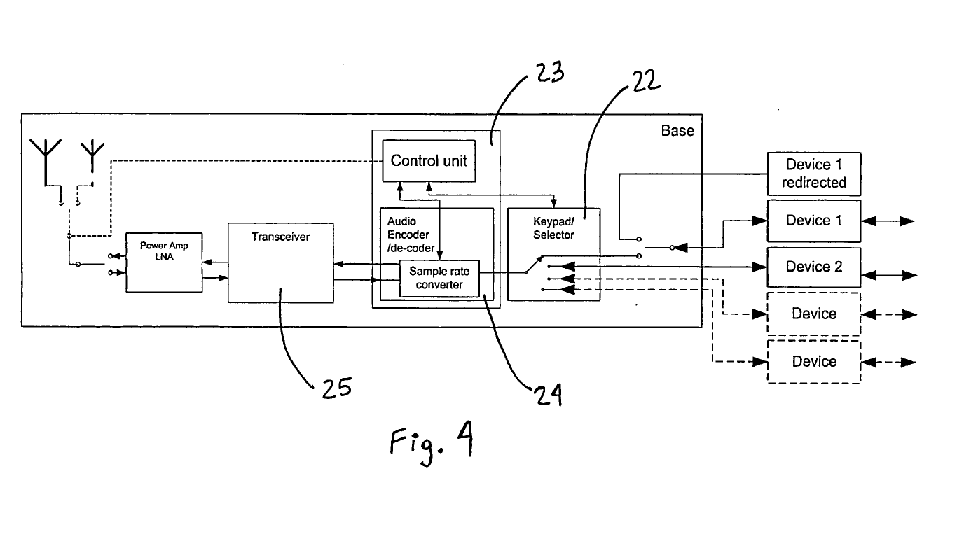

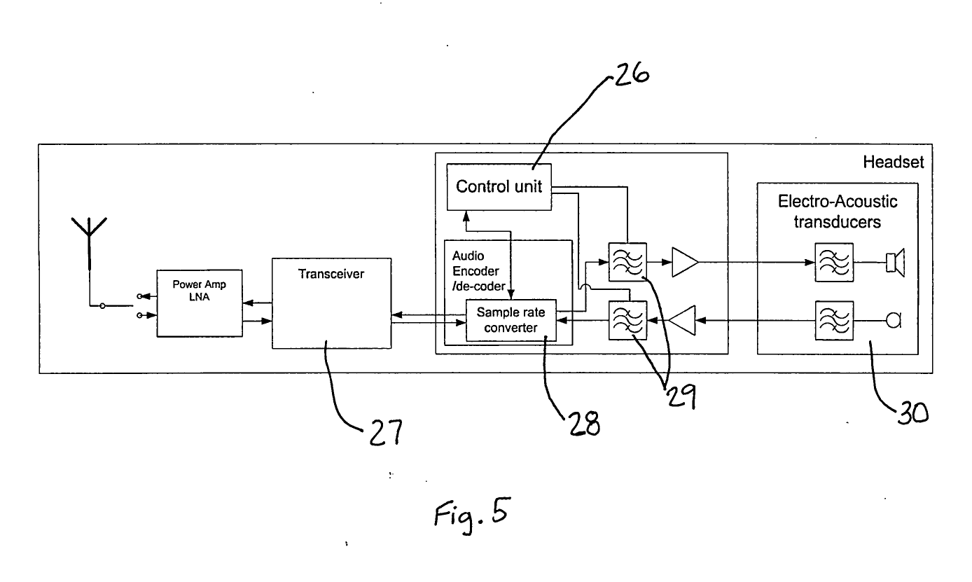

FIG. 4 shows a more detailed block diagram of the base unit of FIG. 2, while

FIG. 5 shows a more detailed block diagram of the communications unit of FIG. 3.

In FIG. 1, the numeral 1 designates a base unit to which a public switched telephone 2 with a receiver 3 is connected via lines 4, 5. The base. unit 1 is powered from a wall adapter 9.

In addition, a PC 6 having a keyboard 7 is connected to the base unit via a line 8 and a generally known USB gate on the PC. This PC may be configured with a PC phone for use for IP telephony (VoIP).

The base unit 1 is connected via a wireless connection 11 to a mobile communications unit, shown here as a headset 10.

FIG. 2 shows the set-up in FIG. 1 by way of a block diagram, but with additional fixed communications units connected to the base unit, said communications units being designated 12, 13 here, which are connected to the base unit 1 via lines 14, 15.

Inside the base unit, there is a control unit which detects whether a call is received from one of the connected, fixed communications units 2, 6, 12 or 13, and, if so, transfers the received call to the antenna 16, following which the mobile unit 18 shown in FIG. 3 may receive the call and answer it via its antenna 22.

Finally, a control circuit may be incorporated in the base unit, ensuring that only one fixed communications unit at a time may transfer a call to the mobile unit. The control circuit may generally be composed of a plurality of switches, each of which is connected to a fixed communications unit. This may be done digitally.

When a fixed communications unit receives a call, its switch will transfer the call via the base unit to the mobile unit, while all other switches will be locked without any possibility of transferring calls. Instead, an engaged tone will be applied in the fixed communications unit.

Depending on which of the fixed communications units receives the call, the base unit may be arranged to transfer the call to the mobile unit at a bandwidth which is suitable for the fixed communications unit.

A bandwidth of e.g. 8 kHz will be suitable when transferring calls to the mobile communications unit from the communications unit 6, which has a PC phone, while a bandwidth of 4 kHz is suitable for the public switched telephone 2.

Other bandwidths, e.g. for the fixed communications units 12, 13, may be used, too. However, in this context it should be mentioned that it is possible for a user to select a fixed bandwidth, e.g. the lowest one, irrespective of which fixed communications unit calls are received from.

As mentioned, the base unit 1 has an antenna 16 for wireless transfer via a wireless connection 11 of signals to a communications unit, which may be a headset 10, as shown in FIG. 1.

The mobile communications unit 18, shown in FIG. 3, has an antenna 22, a speaker 19 and a microphone 20 as well as a plurality of control buttons 21, whose use will be explained below.

In addition to receiving calls via the base unit 1 with its connected, fixed communications units 2, 6, 12, 13, the mobile communications unit may be constructed such that it is possible to make calls from the mobile unit and to select which fixed communications unit is to be used.

This selection may be done either by selection via the control buttons 17 or by selection via the control buttons 21 on the mobile unit. In the latter case, control signals from the mobile unit are transferred wirelessly.

Finally, it should be noted that, within the scope defined by the claims, nothing prevents implementation of the invention with data which are formed by music, images, etc., which have special bandwidth requirements.

The bandwidth may e.g. be adapted to a USB gate which has a higher sample rate, e.g. 44.1 kHz.

FIG. 4 shows a preferred embodiment of the base unit 1 in FIG. 2. A keypad/selector unit 22 serves as a switch, which, either automatically or in response to a user input, selects an input source among the various fixed communications units. In response to the input source, and using a sample rate converter 24, a control circuit 23 (control unit) adapts the bandwidth of the signal, which is transmitted via a transceiver 25 to the mobile communications unit.

The control unit 23 may e.g. receive input from the user via the keyboard 17, cf. FIG. 2, whereby the unit may be forced to a specific bandwidth, e.g. a low bandwidth, which results in a power saving in the mobile communications unit. The base unit may additionally comprise a display (not-shown), which shows the selected input and the current bandwidth. The shown structure of the base unit is particularly expedient in DECT systems. Nothing, however, prevents the base unit from being modified to be applied in other wireless systems, e.g. Bluetooth.

FIG. 5 shows a preferred embodiment of the mobile communications unit 18 in FIG. 3. The unit comprises a control circuit 26 (control unit), which is adapted to apply and receive control signals to and from the control circuit 26 in the base unit containing information on adaptation of the bandwidth in the wireless connection. Using a sample rate converter 28, the control circuit adapts the bandwidth of the signal, which is transmitted to the base unit via a transceiver 27. In addition, the mobile communications unit comprises variable bandpass filters 29 for adapting the signal to and from the transducers 30 of the unit. The mobile communications unit is shown here in a particularly expedient embodiment as a wireless headset of the DECT type, but nothing prevents the unit from operating according to other wireless standards, e.g. Bluetooth.

1. A base unit adapted to provide a communications connection between a plurality of fixed communications units and a mobile communications unit, wherein the base unit contains a control circuit and a plurality of connection terminals for connecting the fixed communications units, said control circuit being arranged to set-up a connection between a selected connection terminal and the mobile communications unit and to adapt the bandwidth in a wireless connection between the base unit and the mobile communications unit in dependence on the selected connection terminal.

2. A base unit according to claim 1, wherein the control circuit is arranged to adapt the bandwidth in the wireless connection in dependence on the bandwidth in an incoming signal on the selected connection terminal.

3. A base unit according to claim 1, wherein the control circuit in the base unit is arranged to receive a control signal from the mobile communications unit and to adapt the bandwidth in the wireless connection in dependence on the control signal.

4. A base unit according to claim 1, wherein the control circuit is arranged to adapt the bandwidth in the wireless connection in dependence on a user input.

5. A base unit according to claim 4, wherein the control circuit is arranged to receive the user input from a keyboard on the base unit.

6. A base unit according to claim 4, wherein the control circuit is arranged to receive the user input from a keyboard on the mobile communications unit.

7. A base unit according to claim 4, wherein the control circuit is arranged to receive a user input which comprises a selection of connection terminal.

8. A base unit (1) according to claim 4, wherein the control circuit is arranged to receive a user input which comprises a selection of a specific bandwidth in the wireless connection.

9. A base unit according to claim 1, wherein it comprises a plurality of switches, which are arranged to selectively set-up a connection between one or more fixed communications units and the mobile communications unit.

10. A base unit according to claim 9, wherein by being arranged to set-up a connection between one or more fixed communications units and the mobile communications unit by precisely one switch.

11. A base unit according to claim 1, wherein it comprises a plurality of USB inputs, a plurality of PSTN inputs, and a plurality of other inputs which enable connection of the fixed communications units.

12. A base unit according to claim 1, wherein by comprising one or more USB inputs which enable connection of a fixed communications unit in the form of a PC phone.

13. A base unit according to claim 1, wherein by comprising one or more PSTN inputs which enable connection of a fixed communications unit in the form of a public switched telephone.

14. A base unit according to claim 1, wherein it is arranged to enable connection of a mobile communications unit in the form of a headset via the wireless connection.

15. A base unit according to claim 1, wherein it is arranged to operate via the wireless connection at bandwidths of 4 kHz or 8 kHz.

16. A method of providing a communications connection between a plurality of fixed communications units and a mobile communications unit via a base unit, said base unit comprising a plurality of connection terminals for connecting the fixed communications units, wherein by setting-up a connection between a selected connection terminal and the mobile communications unit, and adapting the bandwidth in a wireless connection between the base unit and the mobile communications unit in dependence on the selected connection terminal.

17. A method according to claim 16, wherein by adapting the bandwidth in the wireless connection in dependence on the bandwidth of an incoming signal on the selected connection terminal.

18. A method according to claim 16, wherein by adapting the bandwidth in the wireless connection in dependence on a control signal from the mobile communications unit.

19. A method according to claim 16, wherein by adapting the bandwidth in the wireless connection in dependence on a user input.

20. A method according to claim 19, wherein the user input comprises a user's selection of connection terminal.

21. A method according to claim 19, wherein the user input comprises a user's selection of a specific bandwidth in the wireless connection.

22. A method according to claim 16, wherein by selectively setting-up a connection between one or more fixed communications units and the mobile communications unit.

23. A method according to claim 22, wherein by setting-up a connection between one or more fixed communications units and the mobile communications unit by precisely one switch.
